(19) United States
(12) Patent Application Publication
(10) Pub. No.: US 2026/0310105 A1
(43) Pub. Date: Oct. 8, 2026

(54) Precise, High Throughput Optical Imaging Of Packaged Devices

(71) Applicant: KLA Corporation, Milpitas, CA (US)

(72) Inventors: Tal Goichman, Kiryat Ono (IL); Ashkan Aghajani, Eliav (IL); Arkady Bronfman, Beer-Shiva (IL)

(21) Appl. No.: 19/173,117

(22) Filed: Apr. 8, 2025

(51) Int. Cl. G03F 7/00

(52) U.S. Cl. CPC G03F 7/70653; G03F 7/706849; G03F 7/70725; G03F 7/70775; G03F 7/70825; G03F 7/70833

(57) ABSTRACT

Methods and systems for high precision, high throughput, three-dimensional imaging of packaged devices with a small equipment footprint is described herein. In preferred embodiments, a three dimensional imaging system is integrated with additional equipment stations to perform other inspection and metrology applications within a shared equipment footprint. In one aspect, a packaged device measurement system includes a three dimensional imaging system including an optical imaging subsystem, and a sample positioning subsystem mounted to a stiff, massive, vertically oriented, perimeter frame structure. The stiffness and mass of the frame minimizes relative movement of the optical elements of the optical imaging subsystem with respect to the sample under measurement despite force disturbances imposed on the packaged device measurement system from surrounding equipment and rapid movements of the imaging and sample positioning subsystems.

### TECHNICAL FIELD

The described embodiments relate to systems for packaged device inspection, metrology, or both, and more particularly to packaged semiconductor device inspection and metrology modalities.

### BACKGROUND INFORMATION

Semiconductor devices such as logic and memory devices are typically fabricated by a sequence of processing steps applied to a substrate or wafer. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices by a process commonly referred to as die singulation. Singulated semiconductor devices are subsequently tested and packaged. In general, one or more singulated semiconductor devices are packaged into a casing that protects the semiconductor devices from the operating environment, facilitates heat removal, and provides facilities for electrical interconnection of the semiconductor device with the application environment.

Measurements, including both inspection and metrology processes, are used at various steps during a semiconductor manufacturing process, including packaged devices. Packaged device inspection and metrology involves a wide array of checks on package integrity, including geometric dimensions, structural integrity, electrical performance, etc., to promote higher packaged device yield. However, as design rules shrink in size and package complexity increases, inspection and metrology systems are required to capture a wider range of physical defects while maintaining high throughput.

Packaged device inspection and metrology systems often include optical inspection subsystems to illuminate and detect geometric features of a packaged device for undesired defects. As semiconductor design rules continue to evolve, the minimum defect size that must be detected continues to shrink in size.

Traditional optical inspection techniques are based on planar, two-dimensional optical inspection. These techniques are effective to detect in-plane defects (e.g., defects present in a plane less than a few micrometers thick), but are less effective for the detection of defects present in three dimensional structures, e.g., solder bumps, characterized by out of plane dimensions on the order of tens of micrometer, hundreds of micrometers, or greater.

In some examples, confocal optical inspection is employed at different depths. Confocal imaging eliminates spurious or nuisance optical signals from structures above and below the focal plane. Images collected at different depths of focus are combined mathematically to generate three dimensional images of three dimensional structures. Unfortunately, due to the very small depth of focus of the confocal optical system, sample position stability during image capture is critical to ensure high resolution three dimensional images.

Conventional packaged device measurement systems include one or more stations mounted onto a common table. One or more robots move trays of packaged devices from station to station for inspection or metrology of different features of each packaged device. Integration of a confocal optical inspection station as part of a conventional packaged device measurement system is complicated by the required position stability between the confocal optics and the packaged device under inspection. In some embodiments, in-plane position stability of less than one micrometer and position stability in the direction of focus of less than 500 nanometers during image capture is required to achieve sufficiently high resolution three dimensional images. Unfortunately, conventional packaged device measurement systems lack sufficient structural stiffness, structural damping, and mass to achieve the required positioning stability requirements without excessively long move and settle times, if at all.

Packaged device measurement systems are used within the semiconductor industry to detect packaged device defects. Improvements in position control of packaged devices with respect to an optical inspection subsystem are desired.

### SUMMARY

Methods and systems for high precision, high throughput, three-dimensional imaging of packaged devices with a small equipment footprint is described herein. In preferred embodiments, a three dimensional imaging system is integrated with additional equipment stations to perform other inspection and metrology applications within a shared equipment footprint.

In one aspect, a packaged device measurement system includes a three dimensional imaging system including an optical imaging subsystem, and a sample positioning subsystem mounted to a stiff, massive, vertically oriented, perimeter frame structure. The stiffness and mass of the frame minimizes relative movement of the optical elements of the optical imaging subsystem with respect to the sample under measurement despite force disturbances imposed on the packaged device measurement system from surrounding equipment and rapid movements of the imaging subsystem and sample positioning subsystems.

A vertically oriented, perimeter frame provides a structurally enclosed frame with mounting locations for the optical imaging subsystem and the sample positioning subsystem. Moreover, the vertical orientation enables a small footprint for the packaged device measurement system, i.e., the projection of the packaged device measurement system on the floor of a semiconductor fabrication facility is smaller than architectures that require separate machines for three dimensional imaging and other inspection and metrology equipment.

From a structural dynamics perspective, the three dimensional imaging system is partially decoupled mechanically from other inspection and metrology subsystems of an integrated packaged device measurement system. This enables high precision positioning of packaged device samples with respect to a three dimensional optical imaging subsystem with reduced sensitivity to exogenous disturbance forces, e.g., disturbance forces from the other inspection and metrology subsystems of the integrated tool and disturbance forces from other tools installed in a semiconductor fabrication facility.

In a further aspect, the packaged device measurement system includes a horizontally oriented equipment table including one or more equipment stations including equipment to perform different inspection or metrology processes on packaged device samples. The horizontally oriented table is either directly or indirectly mechanically coupled to the three dimensional imaging system. In this sense, the three dimensional imaging system is integrated with other inspection and metrology equipment tasked with inspection and metrology of the same packaged device samples.

In some embodiments, the three dimensional imaging system includes a focal positioning subsystem to control the position of the optical imaging subsystem with respect to the vertically oriented, perimeter frame in the direction of focus of three dimensional imaging system.

The sample positioning subsystem controls the position of a tray of packaged devices with respect to the vertically oriented, perimeter frame in the two direction perpendicular to the direction of focus of the three dimensional imaging system.

The optical imaging subsystem includes an illuminator and a detector. The illuminator provides an amount of illumination light to a singulated packaged device disposed on a tray. The detector detects light collected from packaged device in response to the illumination light. In preferred embodiments, the detector is an imaging detector and the output of the detector is an image of the packaged device at the focal plane of the optical system during image capture by the detector. Images are collected by the detector at each of a number of different focal plane positions to image different depths of the packaged device. The set of collected images are aggregated to form a three dimensional volume image of a packaged device.

In another aspect, the stiffness of the top structural element with respect to the bottom structural element of a vertically oriented, perimeter frame is higher than the stiffness of the structural connection between the equipment table and the vertically oriented, perimeter frame.

In another aspect, the dimension of maximum extent across the width of the perimeter frame is at least three times the dimension of maximum extent across the depth of the perimeter frame.

In a further aspect, the dimension of maximum extent of the height dimension of the perimeter frame is at least two times the dimension of maximum extent across the depth of the perimeter frame. As a result, the perimeter frame structure is predominately vertical. This results in a minimal footprint, i.e. projection of perimeter frame on the floor of a factory in which the system is installed.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a packaged device measurement system 100 configured to perform high throughput measurements of packaged devices in one embodiment.

FIG. 2 is a simplified diagram illustrative of a perspective view of the vertically oriented, perimeter frame mechanically coupled to the pedestal frame referenced in FIG. 1.

FIG. 3 is a simplified diagram illustrative of a side view of the packaged device measurement system depicted in FIG. 1.

FIG. 4 is a simplified diagram illustrative of a side view of a packaged device measurement system in another embodiment.

FIG. 5 depicts packaged device measurement system in another embodiment.

FIG. 6 is a simplified schematic view of one embodiment of an optical imaging subsystem configured to image packaged devices in three-dimensions.

FIG. 7 illustrates a flowchart of an exemplary method for imaging packaged semiconductor devices in at least one novel aspect.

### DETAILED DESCRIPTION

Reference will now be made in detail to background examples and some embodiments of the invention, examples of which are illustrated in the accompanying drawings.

Methods and systems for high precision, high throughput, three-dimensional imaging of packaged devices with a small equipment footprint is described herein. Three dimensional imaging of packaged devices enables high throughput, accurate inspection and metrology of various features of packaged devices, including, but not limited to, solder balls, interconnect leads, solder pads, package surface irregularities, passive device dimensions, such as capacitor height, etc. In preferred embodiments, a three dimensional imaging system is integrated with additional equipment stations to perform other inspection and metrology applications within a shared equipment footprint.

In one aspect, a packaged device measurement system includes a three dimensional imaging system including an optical imaging subsystem, and a sample positioning subsystem mounted to a stiff, massive, vertically oriented, perimeter frame structure. The stiffness and mass of the frame minimizes relative movement of the optical elements of the optical imaging subsystem with respect to the sample under measurement despite force disturbances imposed on the packaged device measurement system from surrounding equipment and movements of the imaging subsystem and sample positioning subsystems.

In a further aspect, the packaged device measurement system includes a horizontally oriented equipment table including one or more equipment stations including equipment to perform different inspection or metrology processes on packaged device samples. The horizontally oriented table is either directly or indirectly mechanically coupled to the three dimensional imaging system. In this sense, the three dimensional imaging system is integrated with other inspection and metrology equipment tasked with inspection and metrology of the same packaged device samples.

From a structural dynamics perspective, the stiffness and mass of the vertically oriented, perimeter frame partially decouples the three dimensional imaging system from other inspection and metrology subsystems of an integrated packaged device measurement system. This enables high precision positioning of packaged device samples with respect to a three dimensional optical imaging subsystem with reduced sensitivity to exogenous disturbance forces, e.g., disturbance forces from the other inspection and metrology subsystems of the integrated tool and disturbance forces from other tools installed in a semiconductor fabrication facility.

A vertically oriented, perimeter frame provides a structurally enclosed frame with mounting locations for the optical imaging subsystem and the sample positioning subsystem. Moreover, the vertical orientation enables a small footprint for the packaged device measurement system, i.e., the projection of the packaged device measurement system on the floor of a semiconductor fabrication facility is smaller than architectures that require separate machines for three dimensional imaging and other inspection and metrology equipment.

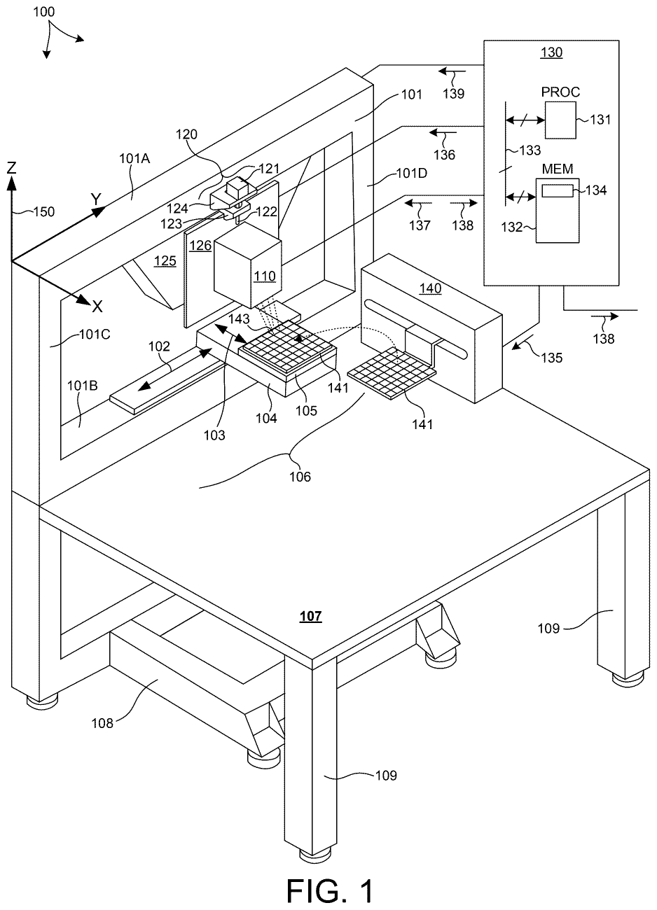

FIG. 1 is a diagram illustrative of a packaged device measurement system 100 in one embodiment. As depicted in FIG. 1, packaged device measurement system 100 includes a vertically oriented, perimeter frame 101 mounted to a pedestal 108, and an equipment table 107 mounted to pedestal 108, and further supported by table legs 109.

The vertically oriented, perimeter frame 101 includes a bottom structural element 101B extending horizontally in the Y-direction as indicated by orthogonal coordinate frame 150, a top structural element 101A also extending in the Y-direction. The top structural element 101A is offset from the bottom structural element 101B vertically in a Z-direction as indicated by orthogonal coordinate frame 150. The vertically oriented, perimeter frame 101 also includes two upright structural elements extending in the Z-direction from the bottom structural element 101B to the top structural element 101A. Upright structural element 101C extends from bottom structural element 101B to top structural element 101A at one end of the top and bottom structural elements. Upright structural element 101D extends from bottom structural element 101B to top structural element 101A at the opposite end of the top and bottom structural elements, i.e., opposite ends of the top and bottom structural elements in the Y-direction.

In the embodiment depicted in FIG. 1, a three dimensional imaging system includes the vertically oriented, perimeter frame 101, optical imaging subsystem 110, sample positioning subsystem 106, computing system 130, and optionally, focal positioning subsystem 120.

In the embodiment depicted in FIG. 1, focal positioning subsystem 120 controls the position of optical imaging subsystem 110 with respect to the vertically oriented, perimeter frame 101 in the Z-direction. Mounting plate 126 is constrained to move with respect to the vertically oriented, perimeter frame 101 in the Z-direction by linear bearing elements (not shown). Motor mounting bracket 124 mechanically couples rotary motor 121 to the vertically oriented, perimeter frame 101. A rotary ball screw 122 is coupled to the output shaft of rotary motor 121. Ball nut 123 is mechanically coupled to mounting plate 126. In this manner a rotation of rotary motor 121 and ball screw 122 results in a linear movement of mounting plate 126. In some embodiments, the position of mounting plate 126 with respect to the vertically oriented, perimeter frame 101 is measured directly using a linear measurement device, e.g., a linear encoder, linear inductive probe, etc. In some other embodiments, the position of mounting plate 126 with respect to the vertically oriented, perimeter frame 101 is measured indirectly using a rotary measurement device, e.g., a rotary encoder, a pulse counter integrated with a rotary stepper type motor, etc., whose output corresponds to the linear position of mounting plate 126. As depicted in FIG. 1, command signals 136 are communicated from computing system 130. In response, the focal positioning subsystem 120 positions mounting plate 126 with respect to perimeter frame 101 in accordance with command signals 136. In this manner, computing system 130 controls the position of mounting plate 126 with respect to perimeter frame 101.

In the embodiment depicted in FIG. 1, focal positioning subsystem 120 positions optical imaging subsystem 110 in the Z-direction with respect to the packaged device 143 under inspection such that packaged device 143 is within the focal range of optical imaging subsystem 110. Optical imaging subsystem 110 includes focusing mechanisms to move the focal plane of the imaging optics in the Z-direction to gather image data over an imaging range of depths in the Z-direction corresponding to the desired volume of packaged device 143. In this manner, optical imaging subsystem 110 is able to collect the images required to generate a three dimensional image of the desired volume of packaged device 143.

Unfortunately, the range of these focusing mechanisms is limited. To overcome this limitation, the focal positioning subsystem 120 has a much larger range in the Z-direction and is employed to move the entire optical imaging subsystem 110 such that the imaging range of depths in the Z-direction corresponding to the desired volume of packaged device 143 is within the limits of the focusing mechanisms of the optical imaging subsystem 110.

The embodiment depicted in FIG. 1 employs a focal positioning subsystem to move optical imaging subsystem 110 in the Z-direction with respect to packaged device 143. However, in some other embodiments, sample positioning subsystem 106 includes an additional degree of freedom in the Z-direction. This enables sample positioning subsystem 106 to move packaged device 143 in the Z-direction with respect to optical imaging subsystem 110 such that the imaging range of depths in the Z-direction corresponding to the desired volume of packaged device 143 is within the limits of the focusing mechanisms of the optical imaging subsystem 110. In one embodiment, a Z-stage, e.g., a piezo stage, a wedge-type stage, or any other suitable stage, is mounted between X-frame 105 and tray 141 and is configured to move tray 141 with respect to X-frame 105 in the Z-direction. In these embodiments, optical imaging subsystem 110 is mounted directly to perimeter frame 101, and focal positioning subsystem 120 is eliminated.

In some other embodiments, an optical imaging subsystem 110 is designed with a sufficient range of focal positions that additional stage movements of the optical imaging subsystem 110 with respect to packaged device 143, or vice-versa, are not required.

In the embodiment depicted in FIG. 1, sample positioning subsystem 106 controls the position of tray 141, including packaged device 143, with respect to the vertically oriented, perimeter frame 101 in the X and Y directions. In the embodiment illustrated in FIG. 1, sample positioning system moves tray 141 in the horizontal plane, i.e., the X and Y directions, under optical imaging subsystem 110 based on command signals 137 received from computing system 130. The sample positioning system includes Y-frame 104, Y-actuators 102, X-frame 105, and X-actuators 103.

Y-frame 104 is constrained to move with respect to the vertically oriented, perimeter frame 101 in the Y-direction by linear bearing elements (not shown), e.g., linear ball bearings, linear crossed roller bearings, air bearings, etc. Y-actuators 102, e.g., linear motor, rotary motor with cable drive, rotary motor with screw and nut drive, etc., provide the driving force to Y-frame 104. In this manner the linear force imparted on Y-frame 104 by Y-actuators 102 results in a linear movement of Y-frame 102. In some embodiments, the position of Y-frame 104 with respect to the vertically oriented, perimeter frame 101 is measured directly using a linear measurement device, e.g., a linear encoder, linear inductive probe, etc.

Similarly, X-frame 105 is constrained to move with respect to Y-frame 104 in the X-direction by linear bearing elements (not shown), e.g., linear ball bearings, linear crossed roller bearings, air bearings, etc. X-actuators 103, e.g., linear motor, rotary motor with cable drive, rotary motor with screw and nut drive, etc., provide the driving force to X-frame 105. In this manner the linear force imparted on X-frame 105 by X-actuators 103 results in a linear movement of X-frame 105. In some embodiments, the position of X-frame 105 with respect to Y-frame 104 is measured directly using a linear measurement device, e.g., a linear encoder, linear inductive probe, etc.

As depicted in FIG. 1, command signals 139 are communicated from computing system 130. In response, the sample positioning subsystem 106 positions tray 141, including packaged device 143 with respect to perimeter frame 101 in accordance with command signals 139. In this manner, computing system 130 controls the position of packaged device 143 with respect to perimeter frame 101.

In the embodiment depicted in FIG. 1, tray 141 includes an array of cells, each including a singulated, packaged device subject to three dimensional imaging by the depicted three dimensional imaging system, and other and inspection and metrology applications performed by inspection and metrology equipment mounted to table 107.

As depicted in FIG. 1, tray handling subsystem 140 is mechanically coupled to table 107. Tray handling subsystem 140 is configured to load tray 141 of singulated packaged devices onto X-frame 105 of the sample positioning subsystem 106. In some embodiments tray 141 is a tray manufactured to meet the Joint Electron Device Engineering Council (JEDEC) standard administered by the JEDEC Solid State Technology Association. JEDEC trays are stackable to ensure space efficient storage and transportation. Furthermore, JEDEC trays store singulated devices in a manner that holds them in fixed locations with respect to the tray. In this manner, the devices can be moved around quickly without physical damage, and can be located accurately with respect to various inspection and metrology equipment. Tray handling subsystem 140 is depicted in a simplified manner in FIG. 1. In general, a tray handling subsystem may include a set of multiple robots configured to move trays to and from storage pods and to and from various inspection and metrology tools mounted to table 107, in addition to the three dimensional imaging system described herein.

As depicted in FIG. 1, command signals 135 are communicated from computing system 130. In response, the tray positioning subsystem 140 positions tray 141, including packaged device 143 onto sample positioning subsystem 106 in accordance with command signals 135. In this manner, computing system 130 controls the handling of trays with respect to sample positioning subsystem 106.

Optical imaging subsystem 110 includes an illuminator and a detector. The illuminator provides an amount of illumination light to singulated packaged device 143 disposed on tray 141. The detector detects light collected from packaged device 143 in response to the illumination light. In preferred embodiments, the detector is an imaging detector and the output of the detector is an image of the packaged device 143 at the focal plane of the optical system during image capture by the detector.

In some embodiments, the Z-position of the focal plane of the optical imaging system with respect to the packaged device 143 is optically scanned through a range of different z-positions. In these embodiments, alignment of the focus plane of the optical subsystem at each different depth is achieved by optical adjustment that moves the focus plane in the z-direction. Images are collected by the detector at each of a number of different focal plane positions to image different depths of the packaged device. In some other embodiments, the Z-position of the packaged device 143 is scanned through the focal plane of the optical imaging system to image different depths of the packaged device. In this manner, optical imaging subsystem 110 generates a set of focused optical images 138, each of the set of focused optical images at a different location with respect to the packaged device in the Z-direction.

The set of collected images 138 are aggregated by computing system 130 to form a three dimensional volume image of a packaged device measured in two lateral dimensions (e.g., X, Y dimensions) and a number of different depths (i.e., different Z-positions).

Sample positioning subsystem 106 is controlled by computing system 130 to position a packaged device sample, e.g., packaged device 143 in the field of view of optical imaging subsystem 110. Focal positioning subsystem 120 adjusts the Z-position of optical imaging subsystem 110, if required, and then optical imaging subsystem 110 scans the focal plane in the Z-direction through the desired volume of packaged device 143 to obtain the images required to generate a three dimensional image of packaged device 143. After image collection, sample positioning subsystem 106 moves tray 141 such that another packaged device housed in another cell of tray 141 is located within the field of view of optical imaging subsystem 110. This process is repeated at high throughput until all of the packaged devices loaded onto tray 140 are imaged. To ensure high throughput, sample positioning subsystem 106 must move from one cell to the next and settle quickly and accurately to the desired position of tray 141 with respect to optical imaging subsystem 110. Quick movements require large driving forces, i.e., forces generated by the X-actuators 103, Y-actuators 102, or both. These large driving forces excite structural modes within the structures of packaged device measurement system 100.

In another aspect, the stiffness of the top structural element with respect to the bottom structural element of the vertically oriented, perimeter frame is higher than the stiffness of the structural connection between the inspection table and the vertically oriented, perimeter frame. In one example, the frequency of the first structural bending mode of the vertically oriented, perimeter frame 101 is higher than the frequency of the first structural bending mode of the assembly of the horizontal table 107 and the vertically oriented, perimeter frame 101. In this manner, the relative displacement between the optical illuminator and a packaged device under measurement induced by disturbance forces, such as floor vibration, vibration from equipment mounted to table 107, and reaction forces from actuators 102 and 103 is significantly smaller than a scenario where the sample positioning system were mounted to table 107, rather than the bottom structural element of vertically oriented, perimeter frame 101.

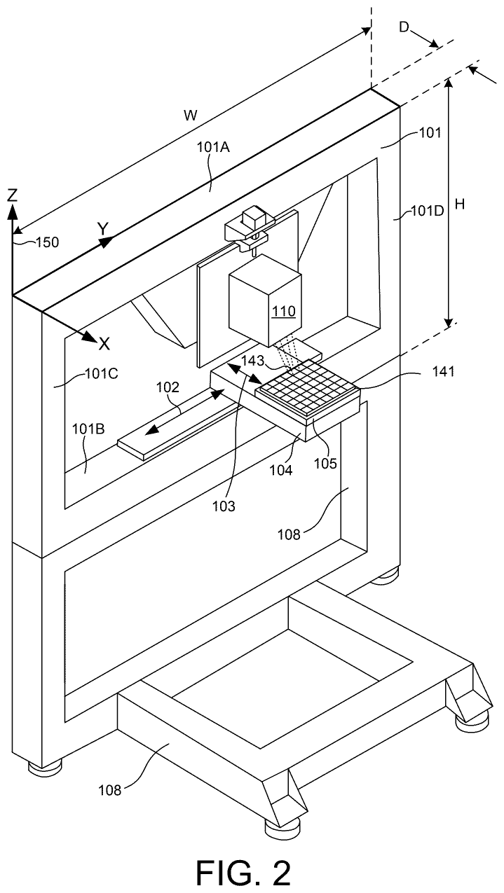

In another aspect, the dimension of maximum extent of the perimeter frame in the Y-direction is at least three times the dimension of maximum extent of the perimeter frame in the X-direction. In a further aspect, the dimension of maximum extent of the perimeter frame in the Z-direction is at least two times the dimension of maximum extent of the perimeter frame in the X-direction. As a result, perimeter frame structure is predominately vertical, i.e., extending further in the Z-direction than at least one of the horizontal dimensions, i.e., the X-direction this example. This results in a minimal footprint, i.e. projection of perimeter frame 101 on the floor of a factory in which system 100 is installed. As depicted in FIG. 2, the dimension of maximum extent of the perimeter frame in the Y-direction is identified as the width, W, the dimension of maximum extent of the perimeter frame in the X-direction is identified as the depth, D, and the dimension of maximum extent of the perimeter frame in the Z-direction is identified as the height, H, of vertically oriented, perimeter frame 101. In this embodiment, the height, H, of vertically oriented, perimeter frame 101 is more than twice the depth, D, of vertically oriented perimeter frame 101, and the width, W, of vertically oriented, perimeter frame 101 is more than three times the depth, D, of vertically oriented perimeter frame 101.

In a preferred embodiment, vertically oriented, perimeter frame 101 is fabricated from granite stone. In some of these embodiments, vertically oriented, perimeter frame 101 is fabricated as one monolithic piece of machined granite stone. In some other embodiments, vertically oriented, perimeter frame 101 is fabricated as a bolted or bonded assembly of multiple pieces of machined granite stone. In one example, the top 101A, bottom 101B, and upright 101C-D structural elements are each fabricated individually, and then bolted or bonded together to form vertically oriented, perimeter frame 101. Granite stone is a preferred material due to its inherent high stiffness, high mass, and high structural damping. For example, granite stone has a damping ratio that is five times the damping ratio of structural steel.

Thus, externally induced vibrations of vertically oriented, perimeter frame 101 do not result in significant relative displacements between the optical imaging subsystem 110 and packaged device 143 under measurement. Furthermore, the relatively high internal structural damping of granite stone promotes rapid dissipation of structural displacements.

Although granite stone is a preferred material, in general, other materials may be contemplated within the scope of this patent document. For example, structural steel and one or more elastomeric materials may be fabricated in layers to promote constrained layer damping. These constrained layer damping structures may be integrated with the perimeter frame or attached to the surface of the frame to promote structural damping sufficient to ensure adequate step and settle performance of packaged device 143 with respect to optical imaging subsystem 110.

As described hereinbefore, high throughput three dimensional imaging of packaged devices arranged on a tray requires a rapid step in position in the X-Y plane from one cell of a tray to the next cell of the tray. Measurement throughput is dictated by the time to make the move and the time for relative motion between the optical imaging subsystem and the tray to settle within specification before measurements can begin, e.g., within 500 nanometers in the Z-direction and one micrometer in the X and Y directions. A primary source of disturbance impacting settling time is modal excitation of the perimeter frame induced by the rapid movement of the moving masses of the sample positioning system. For this reason, the stiffness, mass, and internal structural damping of the vertically oriented, perimeter frame enables higher throughput than previously achieved. In one example, a step and settle movement having a fixed time duration involves a movement of the sample positioning subsystem 106 with a peak velocity of 1 m/s and peak acceleration of 20 m/sec². In an example where a vertically oriented, perimeter frame is employed, the relative motion between optical imaging subsystem 110 and tray 141 is less than 1 micrometer in the X and Y directions, and less than 500 nanometers in the Z direction. In another example, a conventional bridge structure bolted directly to table 107 is employed to support optical imaging subsystem 110 and sample positioning subsystem 106 is also bolted directly to table 107. In this example, the relative motion between optical imaging subsystem 110 and tray 141 is approximately 30-40 micrometers in the X, Y, and Z directions.

As described hereinbefore, vertically oriented, perimeter frame 101 is mechanically coupled to table 107 by a relatively low stiffness mechanical connection, i.e., the stiffness of the top structural element with respect to the bottom structural element of the vertically oriented, perimeter frame is higher than the stiffness of the structural connection between the inspection table and the vertically oriented, perimeter frame.

In some embodiments, a vertically oriented, perimeter frame is coupled to a pedestal frame that supports the vertically oriented, perimeter frame above the floor supporting the packaged device measurement system 100. FIG. 2 is a simplified diagram illustrative of a perspective view of vertically oriented, perimeter frame 101 mechanically coupled to pedestal frame 108. Pedestal frame 108 is in the structural path between the floor and vertically oriented, perimeter frame 101. It is not critical that pedestal frame 108 be especially stiff, or that the mechanical coupling between pedestal frame 108 and vertically oriented, perimeter frame 101 be especially stiff because the high stiffness of vertically oriented, perimeter frame 101 ensures high throughput, high precision positioning performance of packaged device 143 under measurement relative to optical imaging subsystem 101. The stiffness of pedestal frame 108 and the mechanical connection to perimeter frame 101 and table 107 must be sufficient to ensure that relative motion between vertically oriented, perimeter frame 101 and table 107 is sufficiently stable to ensure consistent tray handoff between sample positioning subsystem 106 and tray handling subsystem 140.

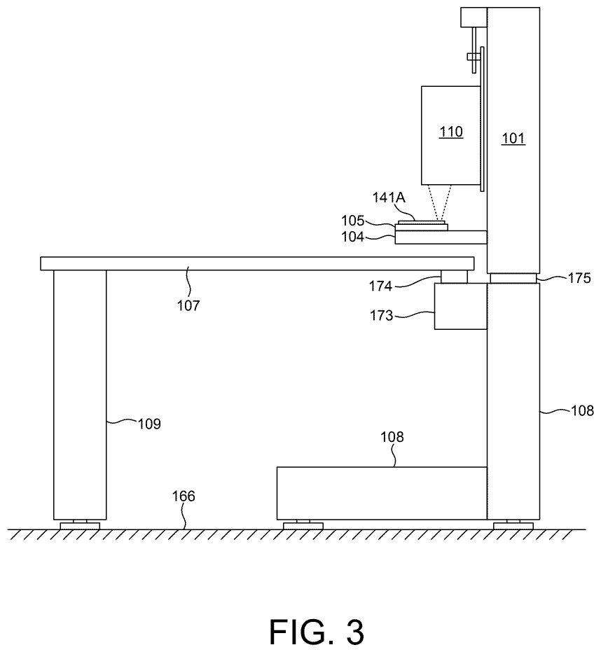

FIG. 3 is a simplified diagram illustrative of a side view of packaged device measurement system 100. As depicted in FIG. 3, pedestal 108 supports both perimeter frame 101 and one end of table 107 above the floor 166. Table legs 109 support the other end of table 107 above floor 166. As depicted in FIG. 3, perimeter frame 101 is mounted to pedestal frame 108 via bolted mounting bushing 175. In some other embodiments, perimeter frame 101 is mounted to pedestal frame 108 via a bolted connection without a mounting bushing.

In addition, as depicted in FIG. 3, pedestal frame 108 includes mounting feature 173 upon which table 107 is connected. In some embodiments, the mounting feature 173 is welded as part of pedestal frame 108. In some other embodiments, mounting feature 173 is bolted to pedestal frame 108. In the embodiment depicted in FIG. 3, table 107 is mounted to mounting feature 173 via bolted mounting bushing 174. In some other embodiments, table 107 is mounted to mounting feature 173 via a bolted connection without a mounting bushing.

In some embodiments, mounting bushings 174 and 175 are fabricated from an elastomeric material, e.g., rubber, polyurethane, etc. However, in general, mounting bushings 174 and 175 may be fabricated from any suitable structural material.

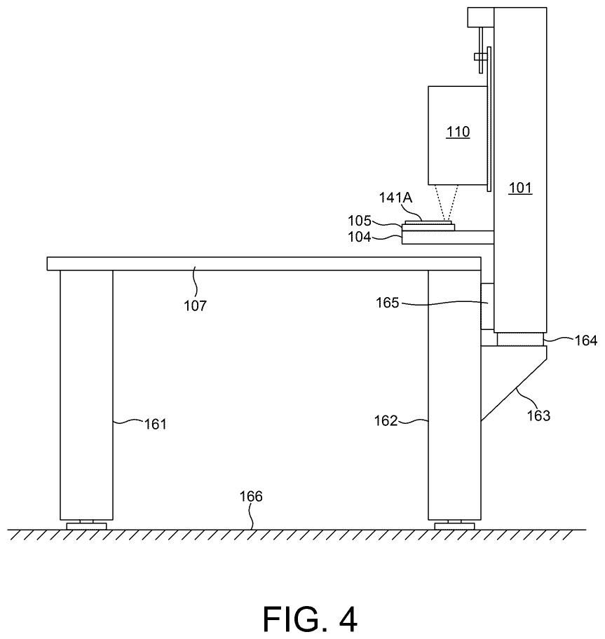

FIG. 4 is a simplified diagram illustrative of a side view of packaged device measurement system 100 in another embodiment. As depicted in FIG. 4, table legs 162 support both perimeter frame 101 and one end of table 107 above the floor 166. Table legs 161 support the other end of table 107 above floor 166. As depicted in FIG. 4, table 107 is mounted to table legs 161 and 162. In general, table legs 161 and 162 are part of a pedestal employed to support table 107 and perimeter frame 101.

As depicted in FIG. 4, table leg 162 includes mounting feature 163 upon which perimeter frame 101 is connected. In some embodiments, the mounting feature 163 is welded as part of table leg 162. In some other embodiments, mounting feature 163 is bolted to table leg 162. In the embodiment depicted in FIG. 4, perimeter frame 101 is mounted to mounting feature 163 via bolted mounting bushing 164. In some other embodiments, perimeter frame 101 is mounted to mounting feature 163 via a bolted connection without a mounting bushing. In addition, as depicted in FIG. 4, perimeter frame 101 is mounted to table leg 162 via bolted mounting bushing 165. In some other embodiments, perimeter frame 101 is mounted to table leg 162 via a bolted connection without a mounting bushing.

In some embodiments, mounting bushings 164 and 165 are fabricated from an elastomeric material, e.g., rubber, polyurethane, etc. However, in general, mounting bushings 164 and 165 may be fabricated from any suitable structural material.

In some other embodiments, perimeter frame 101 is mounted adjacent to the top surface of table 107 directly via a bolted connection with or without a mounting bushing.

In FIGS. 3-4, various illustrated mechanical connections are implemented with bolted mounting bushings. However, in general, other low stiffness mechanical connections may be contemplated within the scope of this patent document. By way of non-limiting example, mechanical flexures may be implemented as the mechanical connection between perimeter frame 101 and pedestal 108, table leg 162, or another structure supporting perimeter frame 101. Similarly, mechanical flexures may be implemented as the mechanical connection between table 107 and pedestal 108, table legs 161 and 162, perimeter frame 101, or any combination thereof.

In another further aspect, perimeter frame 101 includes a subframe element mechanically coupled to the perimeter frame by a hinge mechanism. In an unclamped state, the subframe element is free to rotate about an axis oriented in the Z-direction. In a clamped state, the subframe element is mechanically coupled to perimeter frame 101 by a bolted connection. Optical imaging subsystem 110 is mounted directly, or indirectly, to the subframe element. In this manner, the optical imaging subsystem 110 is easily maneuvered from an operational position that is difficult to physically access to a service position from which a technician can easily access the optical imaging subsystem 110 to perform maintenance and repair tasks.

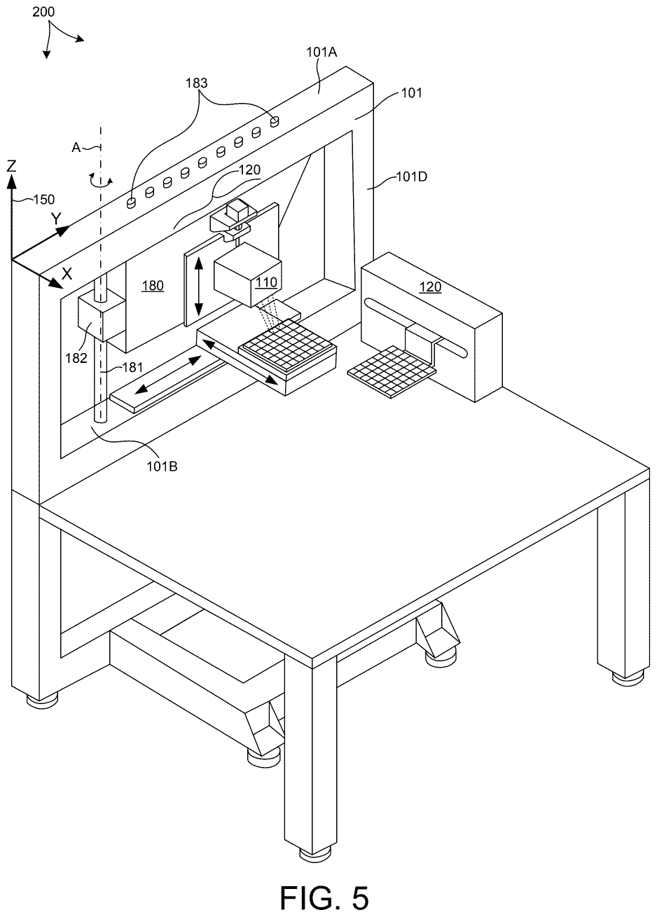

FIG. 5 depicts packaged device measurement system 200 in another embodiment. In the embodiment depicted in FIG. 5, perimeter frame 101 includes subframe element 180. Focal positioning subsystem 120 is mechanically coupled to subframe 180, and optical imaging subsystem 110 is indirectly coupled to subframe 180 via focal positioning subsystem 120. In a clamped state, subframe element 180 is mechanically coupled to the top structural element 101A of perimeter frame 101 by a bolted connection. As depicted in FIG. 5, bolts 183 pass through top structural element 101A and thread into subframe element 180 to mechanically clamp subframe element 180 to top structural element 101A. In an unclamped state, bolts 183 are removed and subframe 180 is supported in the Z-direction by a hinge mechanism that allow free rotation of subframe 180 about axis, A. In the embodiment depicted in FIG. 5, axis, A, is oriented in the Z-direction. In the embodiment depicted in FIG. 5, the hinge mechanism includes a rod structure 181 mechanically coupled to top structural element 101A and bottom structural element 101B. Subframe 180 includes a hinge block 182 including a hole feature through which rod structure 181 extends. In addition, rod structure 180 includes a concentric bushing clamped to rod structure 181 (not shown) immediately below hinge block 182. The concentric bushing acts as a thrust bearing to support subframe 180 in the Z-direction when bolts 183 are removed. As depicted in FIG. 5, subframe 180 is in the operational position. In the unclamped state, subframe 180 is rotatable about axis, A, in a counter-clockwise direction to rotate subframe 180 into a service position behind perimeter frame 101. After service, subframe 180 is rotatable about axis, A, in a clockwise direction back to the operational position. In the operational position, bolts 183 are reinstalled and optical imaging subsystem 110 is ready to resume operations.

Although, the clamping of subframe 180 to perimeter frame 101 is achieved by a bolted connection, in general, any suitable clamping and unclamping mechanism may be contemplated within the scope of this patent document.

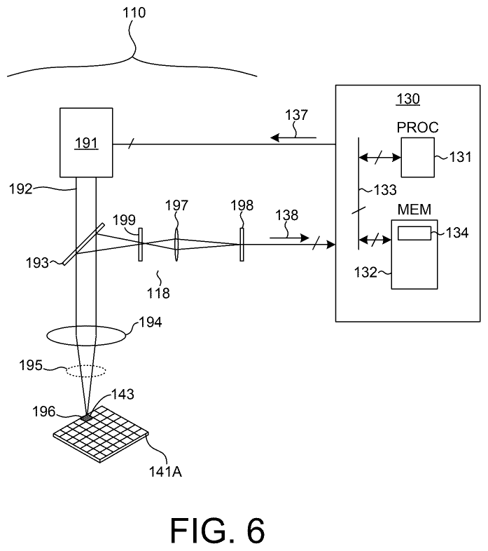

FIG. 6 is a simplified schematic view of one embodiment of an optical imaging subsystem 110 configured to image packaged devices in three-dimensions. Optical inspection subsystem 110 includes an illumination subsystem, a collection subsystem, and one or more detectors. The illumination subsystem includes an illumination source 191 and all optical elements in the illumination optical path from the illumination source to the packaged device under measurement. The collection subsystem includes all optical elements in the collection optical path from the packaged device under measurement to the detector. For simplification, some optical components of the system have been omitted. By way of example, folding mirrors, polarizers, beam forming optics, additional light sources, additional collectors, and detectors may also be included. All such variations are within the scope of the invention described herein.

As illustrated in FIG. 1, a packaged device 143 is illuminated by a normal incidence beam 192 generated by one or more illumination sources 191. Alternatively, the illumination subsystem may be configured to direct the beam of light to the specimen at an oblique angle of incidence. In some embodiments, subsystem 110 may be configured to direct multiple beams of light to the specimen such as an oblique incidence beam of light and a normal incidence beam of light. The multiple beams of light may be directed to the specimen substantially simultaneously or sequentially.

Illumination source 191 may include, by way of example, a broad band laser sustained plasma light source, a laser, a supercontinuum laser, a diode laser, a helium neon laser, an argon laser, a solid state laser, a diode pumped solid state (DPSS) laser, a xenon arc lamp, a gas discharging lamp, an LED array, and an incandescent lamp. The light source may be configured to emit near monochromatic light or broadband light. In some embodiments, the illumination subsystem may also include one or more spectral filters that may limit the wavelength of the light directed to the specimen. The one or more spectral filters may be bandpass filters and/or edge filters and/or notch filters. Illumination may be provided to the specimen over any suitable range of wavelengths. In some examples, the illumination light includes wavelengths ranging from 260 nanometers to 950 nanometers. In some examples, illumination light includes wavelengths greater than 950 nanometers (e.g., extending to 2,500 nanometers). In some embodiments, the illumination subsystem may also include one or more polarization optics that control the polarization of the light directed to the specimen.

Beam 192 generated by illumination source 191 is directed to a beam splitter 193. Beam splitter 193 directs the beam to objective lens 194. Objective lens 194 focuses the beam 195 onto packaged device 143 at incident spot 196. Incident spot 196 is defined (i.e., shaped and sized) by the projection of light emitted from illumination source 191 onto the surface of packaged device 143. In general, the beam 111 and spot 119 can be controlled by the computing system 130, which communicates control signals to illumination source 101. In one example, computing system 130 communicates command signal 137 to illumination source 101. In response, illumination source 101 adjusts the spectral range(s) of the illumination beam 111. In general, the beam 195 that is incident on packaged device 143 may differ from the light emitted by illumination source 191 in one or more ways, including polarization, intensity, size and shape, etc.

Subsystem 110 includes collection optics 197 to collect the light scattered and/or reflected by packaged device 143 and focus that light onto detector 198. The output images 138 generated by detector 198 are communicated to computing system 130 for processing.

Collection optics 197 may be a lens, a compound lens, or any appropriate lens known in the art. Alternatively, any of collection optics 197 may be a reflective or partially reflective optical component, such as a mirror. In addition, although particular collection angles are illustrated in FIG. 6, it is to be understood that the collection optics may be arranged at any appropriate collection angle. The collection angle may vary depending upon, for example, the angle of incidence and/or topographical characteristics of the specimen. In some embodiments, subsystem 110 also includes selectable collection polarization elements.

Detector 198 generally functions to convert the reflected and scattered light into an electrical signal, and therefore, may include substantially any photodetector known in the art. However, a particular detector may be selected for use within one or more embodiments of the invention based on desired performance characteristics of the detector, the type of packaged device to be imaged, and the configuration of the illumination. For example, if the amount of light available for inspection is relatively low, an efficiency enhancing detector such as a time delay integration (TDI) camera may increase the signal-to-noise ratio and throughput of the system. However, other detectors such as charge-coupled device (CCD) cameras, photodiodes, phototubes and photomultiplier tubes (PMTs) may be used, depending on the amount of light available for imaging and the type of imaging being performed.

Subsystem 110 can use various imaging modes, such as bright field and dark field modes. For example, in one embodiment, detector 198 generates a bright field image. As illustrated in FIG. 6, some amount of light scattered from the surface of packaged device 143 at a narrow angle is collected by objective lens 194. This light passes back through objective lens 194 and impinges on beam splitter 193. Beam splitter 193 transmits a portion of the light to collection optics 197, which in turn focuses the light onto detector 198. In this manner a bright field image is generated by detector 198. Collection optics 197 includes an imaging lens that images the reflected light collected by objective lens 194 onto detector 198. An aperture or Fourier filter 199 is placed at the back focal plane of objective lens 194. Various imaging modes such as bright field, dark field, and phase contrast can be implemented by using different illumination apertures, collection apertures, Fourier filters, or combinations thereof. The configuration of the imaging mode, such as illumination direction or imaging collection solid angle, can be determined based on measured three-dimensional images. U.S. Pat. Nos. 7,295,303 and 7,130,039, which are incorporated by reference herein, describe these imaging modes in further detail. In some other embodiments, detector 198 generates dark field images by imaging scattered light collected at larger field angles. U.S. Pat. No. 6,208,411, which is incorporated by reference herein, describes these imaging modes in further detail.

Subsystem 100 also includes various electronic components (not shown) needed for processing the reflected and/or scattered signals detected by detector 198. For example, subsystem 100 may include amplifier circuitry to receive output signals from detector 198 and to amplify those output signals by a predetermined amount and an analog-to-digital converter (ADC) to convert the amplified signals into a digital format suitable for use within processor 131. In one embodiment, the processor may be coupled directly to an ADC by a transmission medium. Alternatively, the processor may receive signals from other electronic components coupled to the ADC. In this manner, the processor may be indirectly coupled to the ADC by a transmission medium and any intervening electronic components.

In a further aspect, a three dimensional image of a packaged device is generated from a volume measured in two lateral dimensions (e.g., X and Y directions) and a depth dimension (e.g., Z-direction). In the embodiment depicted in FIG. 1, computing system 130 arranges the images generated by detector 198 into a volumetric data set that corresponds to the measured volume.

In one example, a series of images are acquired from a packaged device for a number of different Z-locations. In this example, computing system 130 generates a three-dimensional image of the measured volume by assembling a stack of the series of two-dimensional images acquired at each different focal location.

In another aspect, defect analysis, measurement analysis, etc., is performed based on three dimensional images collected from packaged devices as described herein. In some examples, defects are identified, classified, measured, or any combination thereof, based on an analysis of a three dimensional image of a packaged device. In FIG. 1, output signals 138 are communicated from computing system 130 indicative of defects, measurement results, etc., derived from three dimensional images collected from packaged devices as described herein.

In some embodiments, a three-dimensional image stack is plotted using 3D visualization techniques. The resulting renderings are read by an operator who selects defects of interest. In one embodiment, system 100 includes peripheral devices useful to accept inputs from an operator (e.g., keyboard, mouse, touchscreen, etc.) and display outputs to the operator (e.g., display monitor). Input commands from an operator may be used by processor 131 to flag defects. Three dimensional images of an inspected volume may be graphically presented to an operator on a display monitor.

In some embodiments, a three-dimensional image is processed algorithmically to identify and classify defects of interest. In some examples, processor 131 is configured to detect and classify defects from a three-dimensional image. The processor may include any appropriate processor known in the art. In addition, the processor may be configured to use any appropriate defect detection and classification algorithm or method known in the art. For example, the processor may use a die-to-database comparison, a three-dimensional filter, a clustering algorithm such as a principal component analysis or spectral clustering, a thresholding algorithm, a deep learning algorithm, or any other suitable algorithm to detect and classify defects on the specimen.

In another aspect, a three dimensional location of a defect of interest is determined based on an analysis of the three dimensional image of a packaged device. In this manner, the actual position of a defect of a packaged device is measured (e.g., {x, y, z} coordinates of the defect). The actual defect position can be used to locate the defect later for further analysis.

In general, computing system 130 is configured to perform three dimensional imaging and analysis of packaged devices using images obtained from a detector. The computing system 130 may include any appropriate processor(s) known in the art. In addition, the computing system 130 may be configured to use any appropriate analysis algorithm or method known in the art. For example, the computing system 130 may use a die-to-database comparison or a thresholding algorithm to detect defects on the specimen.

In addition, packaged device measurement system 100 may include peripheral devices useful to accept inputs from an operator (e.g., keyboard, mouse, touchscreen, etc.) and display outputs to the operator (e.g., display monitor). Input commands from an operator may be used by computing system 130 to adjust threshold values used to control illumination power. The resulting power levels may be graphically presented to an operator on a display monitor.

Packaged device measurement system 100 includes a processor 131 and an amount of computer readable memory 132. Processor 131 and memory 132 may communicate over bus 133. Memory 132 includes an amount of memory 134 that stores an amount of program code that, when executed by processor 131, causes processor 131 to execute the defect detection, classification, and depth estimation functionality described herein.

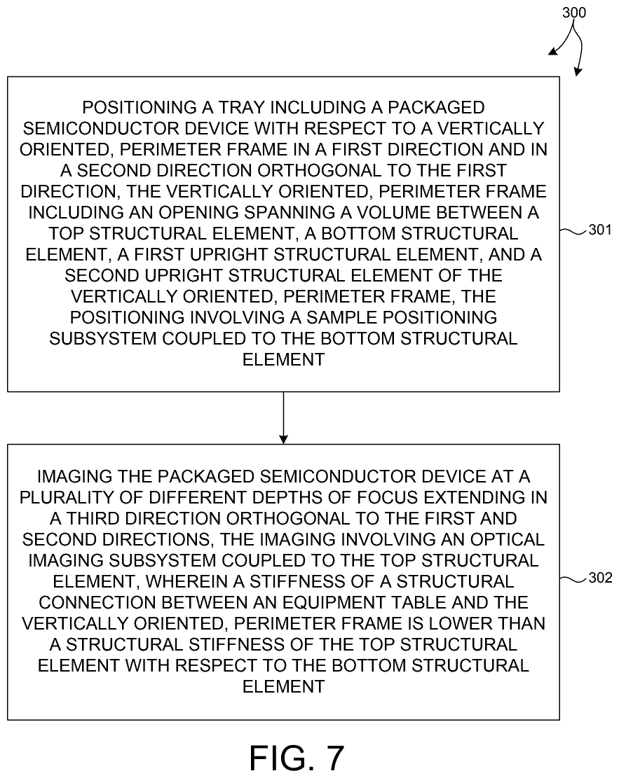

FIG. 7 illustrates a flowchart of an exemplary method 300 useful for imaging packaged semiconductor devices in at least one novel aspect. In some non-limiting examples, packaged device measurement systems 100 and 200 described with reference to FIGS. 1 and 5, respectively, are configured to implement method 200. However, in general, the implementation of method 200 is not limited by the specific embodiments described herein.

In block 301, a tray including a packaged semiconductor device is positioned with respect to a vertically oriented, perimeter frame in a first direction and in a second direction orthogonal to the first direction. The vertically oriented, perimeter frame including an opening spanning a volume between a top structural element, a bottom structural element, a first upright structural element, and a second upright structural element of the vertically oriented, perimeter frame. The positioning involves a sample positioning subsystem coupled to the bottom structural element.

In block 302, the packaged semiconductor device is imaged at a plurality of different depths of focus extending in a third direction orthogonal to the first and second directions. The imaging involves an optical imaging subsystem coupled to the top structural element. A stiffness of a structural connection between an equipment table and the vertically oriented, perimeter frame is lower than a structural stiffness of the top structural element with respect to the bottom structural element.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A packaged device measurement system, comprising:
a vertically oriented, perimeter frame including a bottom structural element extending in a first direction, a top structural element extending in the first direction and offset from the bottom structural element in a second direction perpendicular to the first direction, a first upright structural element extending in the second direction from the bottom structural element to the top structural element at a first end of the top and bottom structural elements, and a second upright structural element extending in the second direction from the bottom structural element to the top structural element at a second end of the top and bottom structural elements opposite the first end;
an optical imaging subsystem including an illuminator and a detector configured to generate a set of images of a packaged device, each image of the set of images focused at a different depth of the packaged device; and
a sample positioning subsystem mechanically coupled to the bottom structural element of the vertically oriented, perimeter frame, the sample positioning subsystem disposed between the bottom structural element and the top structural element and between the first and second upright structural elements, the sample positioning subsystem including a linear motion stage configured to move a tray including the packaged device with respect to the optical imaging subsystem in the first direction and in a third direction orthogonal to the first and second directions.

2. The packaged device measurement system of claim 1, further comprising:
a tray handling subsystem mechanically coupled to an equipment table, the tray handling subsystem configured to load the tray including the packaged device from the equipment table onto the sample positioning system.

3. The packaged device measurement system of claim 2, wherein a stiffness of a structural connection between the equipment table and the vertically oriented, perimeter frame is lower than a structural stiffness of the top structural element with respect to the bottom structural element.

4. The packaged device measurement system of claim 1, further comprising:
a first pedestal frame in a structural path from a floor supporting the packaged device measurement system to the bottom structural element, the equipment table mechanically coupled to the first pedestal.

5. The packaged device measurement system of claim 1, further comprising:
a focal positioning subsystem mechanically coupled to the vertically oriented, perimeter frame, the focal positioning subsystem including a linear motion stage configured to move the optical imaging subsystem with respect to the vertically oriented, perimeter frame in the second direction.

6. The packaged device measurement system of claim 1, the linear motion stage of the sample positioning subsystem further configured to move the tray including the packaged device with respect to the optical imaging subsystem in the second direction.

7. The packaged device measurement system of claim 1, further comprising:
a hinge mechanism mechanically coupled to the vertically oriented, perimeter frame, the hinge mechanism having an axis of rotation oriented in the second direction; and
a subframe element, wherein in a clamped state the subframe element is mechanically fixed to the vertically oriented, perimeter frame, wherein in an unclamped state the subframe element is free to rotate about axis of rotation of the hinge mechanism, and wherein the optical imaging subsystem is coupled to the subframe element.

8. The packaged device measurement system of claim 1, further comprising:
a computing system configured to:
receive the set of images each focused at a different depth of the packaged device; and
generate a three dimensional image of an inspected volume of the packaged device based on the set of images.

9. The packaged device measurement system of claim 1, wherein a dimension of maximum extent of the vertically oriented, perimeter frame in the first direction is at least three times a dimension of maximum extent of the vertically oriented, perimeter frame in the third direction.

10. The packaged device measurement system of claim 1, wherein a dimension of maximum extent of the vertically oriented, perimeter frame in the second direction is at least two times a dimension of maximum extent of the vertically oriented, perimeter frame in the third direction.

11. The packaged device measurement system of claim 1, wherein the vertically oriented, perimeter frame is fabricated from granite stone.

12. A method comprising:
positioning a tray including a packaged semiconductor device with respect to a vertically oriented, perimeter frame in a first direction and in a second direction orthogonal to the first direction, the vertically oriented, perimeter frame including an opening spanning a volume between a top structural element, a bottom structural element, a first upright structural element, and a second upright structural element of the vertically oriented, perimeter frame, the positioning involving a sample positioning subsystem coupled to the bottom structural element; and
imaging the packaged semiconductor device at a plurality of different depths of focus extending in a third direction orthogonal to the first and second directions, the imaging involving an optical imaging subsystem coupled to the top structural element, wherein a stiffness of a structural connection between an equipment table and the vertically oriented, perimeter frame is lower than a structural stiffness of the top structural element with respect to the bottom structural element.

13. The method of claim 12, further comprising:
generating a three-dimensional image of the imaged volume spanned by the imaging of the packaged semiconductor device at each of the plurality of different depths of focus; and
measuring a structural feature of the packaged semiconductor device based on the three-dimensional image.

14. The method of claim 12, further comprising:
positioning the optical imaging subsystem with respect to the vertically oriented, perimeter frame in the third direction.

15. The method of claim 12, wherein a dimension of maximum extent of the vertically oriented, perimeter frame in the first direction is at least three times a dimension of maximum extent of the vertically oriented, perimeter frame in the second direction.

16. The method of claim 12, wherein a dimension of maximum extent of the vertically oriented, perimeter frame in the third direction is at least two times a dimension of maximum extent of the vertically oriented, perimeter frame in the second direction.

17. The method of claim 12, wherein the vertically oriented, perimeter frame is fabricated from granite stone.

18. A packaged device measurement system, comprising:
a vertically oriented, perimeter frame including a bottom structural element, a top structural element a first upright structural element, and a second upright structural element;
a sample positioning subsystem mechanically coupled to the bottom structural element and disposed between the bottom structural element and the top structural element and between the first and second upright structural elements, the sample positioning subsystem including a linear motion stage configured to move a tray including a packaged device with respect to the vertically oriented, perimeter frame in a first direction and a second direction orthogonal to the first direction; and
an optical imaging subsystem including an illuminator and a detector configured to generate a set of images of a packaged device, each image of the set of images focused at different depths of the packaged device, the different depths extending in a third direction orthogonal to the first and second directions, wherein a stiffness of a structural connection between an equipment table of the packaged device measurement system and the vertically oriented, perimeter frame is lower than a structural stiffness of the top structural element with respect to the bottom structural element.

19. The packaged device measurement system of claim 18, further comprising:
a focal positioning subsystem mechanically coupled to the vertically oriented, perimeter frame, the focal positioning subsystem including a linear motion stage configured to move the optical imaging subsystem with respect to the vertically oriented, perimeter frame in the third direction.

20. The packaged device measurement system of claim 18, wherein a dimension of maximum extent of the vertically oriented, perimeter frame in the first direction is at least three times a dimension of maximum extent of the vertically oriented, perimeter frame in the second direction, and wherein a dimension of maximum extent of the vertically oriented, perimeter frame in the third direction is at least two times a dimension of maximum extent of the vertically oriented, perimeter frame in the second direction.
